(19) United States
(12) Patent Application Publication
(10) Pub. No.: US 2008/0315379 A1
(43) Pub. Date: Dec. 25, 2008

(54) Semiconductor packages including thermal stress buffers and methods of manufacturing the same

(75) Inventors: Ku-Young Kim, Seoul (KR); Hyung-gil Baek, Suwon-si (KR); Jong-gi Lee, Yongin-si (KR); Sang-wook Park, Cheonan-si (KR); Kun-dae Yeom, Cheonan-si (KR); Dong-hun Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/213,325

(22) Filed: Jun. 18, 2008

(30) Foreign Application Priority Data
Jun. 20, 2007 (KR) 10-2007-0060686

(51) Int. Cl. H01L 23/495

(52) U.S. Cl. 257/675; 257/E23.031

(57) ABSTRACT

Provided is a semiconductor package and method of manufacturing the same. The semiconductor package may include a semiconductor chip, an encapsulant encapsulating the semiconductor chip, a lead unit, and a partially encapsulated by the encapsulating thermal stress buffer which absorbs thermal stress of the semiconductor chip or the encapsulant.

### PRIORITY STATEMENT

This application claims priority under 35 U.S.C. § 119 to Korean Patent Application No.10-2007-0060686, filed on Jun. 20, 2007, in the Korean Intellectual Property Office (KIPO), the entire contents of which are herein incorporated by reference.

### BACKGROUND

1. Field

Example embodiments relate to a semiconductor package and a method of manufacturing the same. More particularly, example embodiments relate to a semiconductor package in which soldering failure of a lead unit may be prevented or reduced even when warpage of the semiconductor package occurs due to temperature variations.

2. Description of the Related Art

A semiconductor package may be fabricated by putting a semiconductor chip on a lead frame, encapsulating the lead frame and the semiconductor chip with an encapsulant, and exposing outer leads outside the encapsulant. A plurality of semiconductor packages may be stacked on a module printed circuit board (PCB). Various packaging methods have been suggested in accordance with a method of stacking the semiconductor packages and a method of arranging the outer leads.

FIG. 1 is a cross-sectional view of conventional first and second semiconductor packages 11 and 12 in which warpage may occur due to temperature variations caused by heat that may be generated when the first and second semiconductor packages 11 and 12 are operated.

Referring to FIG. 1, the first and second semiconductor packages 11 and 12 may be formed by stacking different elements, e.g., lead frames 20, semiconductor chips 25, and first and second lead units 31 and 32, which may have different thermal expansion coefficients. The first and second semiconductor packages 11 and 12 may be mounted on a module PCB 40. The first and second semiconductor packages 11 and 12, the module PCB 40, and first and second solder units 51 and 52 may have different thermal expansion coefficients from each other. Furthermore, the first and second semiconductor packages 11 and 12 may have different thermal expansion coefficients.

Differences in thermal expansion coefficients among the stacking elements, the module PCB 40, and the first and second semiconductor packages 11 and 12 may be accompanied with different thermal strains in accordance with temperature variations. The different thermal strains may cause warpage of the first and second semiconductor packages 11 and 12 such that thermal stresses may occur in joints between the stacking elements, the module PCB 40, and the first and second semiconductor packages 11 and 12 or the first and second solder units 51 and 52.

The thermal stresses may periodically or repeatedly occur in and act on the joints or the first and second solder units 51 and 52 and may crack or release the joints or the first and second solder units 51 and 52. Accordingly, when the first and second semiconductor packages 11 and 12 are used for a relatively long time, a defect may occur. This defect may affect the reliability of the packages.

Virtual lines 60 illustrate warpage profiles of encapsulants encapsulating the semiconductor chips 25. Virtual lines 61 illustrate warpage profiles of the first lead unit 31 that may be soldered to the second lead unit 32 and the second lead unit 32 that may be soldered to the module PCB 40. Stresses may occur in and cause cracks on the joints between the encapsulants and the lead units due to differences in warpage profiles due to thermal effects. For example, when the first and second semiconductor packages 11 and 12 are sequentially stacked on the module PCB 40 as illustrated in FIG. 1, the warpage profile of the encapsulant of the second semiconductor package 12 may be different from the warpage profile of the second lead unit 32 and may cause thermal stresses to occur in and crack the joints between the encapsulant and the second lead unit 32. If the warpage profile of the first lead unit 31 is different from the warpage profile of the second lead unit 32, the thermal stresses may occur in and cause cracks on the second solder unit 52. If the warpage profile of the module PCB 40 is different from the warpage profile of the first lead unit 31, the thermal stresses may occur in and cause cracks on the first solder unit 51.

### SUMMARY

Example embodiments provide a semiconductor package, the reliability of which is mechanically and/or electrically improved by dispersing and/or absorbing thermal stress that occurs in joints or solder units of the semiconductor package. Example embodiments also provide for a method of manufacturing a semiconductor package.

According to example embodiments, a semiconductor package may include a semiconductor chip, an encapsulant encapsulating the semiconductor chip, a lead unit partially encapsulated by the encapsulant, and a thermal stress buffer which absorbs thermal stress of the semiconductor chip and/or the encapsulant.

According to example embodiments, a method of manufacturing a semiconductor chip may include placing a semiconductor package on a lead frame, forming at least one lead unit to the side of the lead frame, forming at least one thermal stress buffer, and encapsulating the semiconductor chip, the at least one thermal buffer, and the at least one lead unit with an encapsulant.

However, example embodiments are not restricted to the ones set forth herein. The above and other features and advantages of example embodiments will become more apparent to one of ordinary skill in the art to which example embodiments pertain by referencing a detailed description of example embodiments given below.

### BRIEF DESCRIPTION OF THE DRAWINGS

Example embodiments will be more clearly understood from the following detailed description taken in conjunction with the accompanying drawings. FIGS. 2-5 represent non-limiting, example embodiments as described herein.

FIG. 1 is a cross-sectional view of conventional semiconductor packages in which warpage occurs;

FIG. 2 is a cross-sectional view of semiconductor packages in which warpage is reduced or prevented by thermal stress buffers according to example embodiments;

FIG. 3 is a perspective view for illustrating positions of the thermal stress buffers illustrated in FIG. 2 according to example embodiments;

FIG. 4 is a cross-sectional view of semiconductor packages according to example embodiments; and

FIG. 5 is a cross-sectional view of semiconductor packages according to example embodiments.

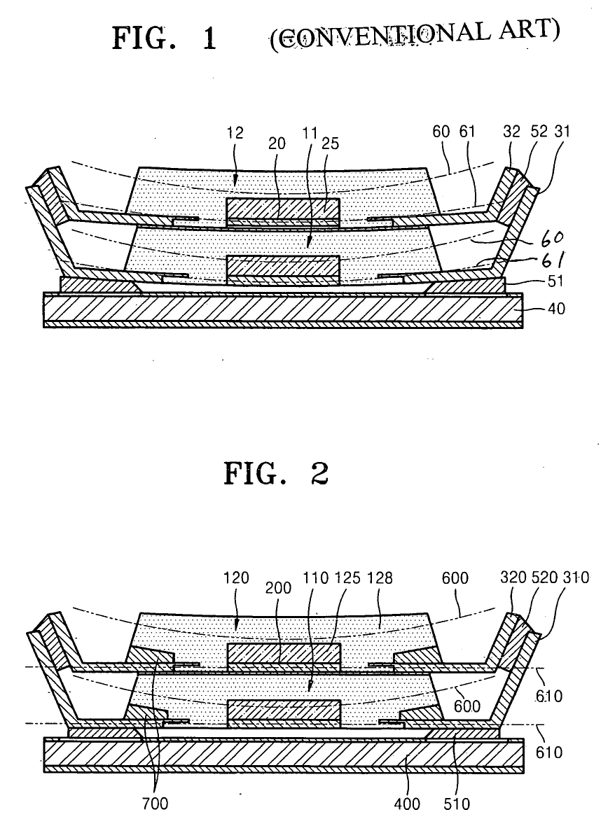

### DETAILED DESCRIPTION OF EXAMPLE EMBODIMENTS

Example embodiments are described more fully hereinafter with reference to the accompanying drawings. Example embodiments may, however, be embodied in many different forms and should not be construed as limited to the embodiments set forth herein. Rather, these embodiments are provided so that this disclosure will be thorough and complete, and will fully convey the scope of example embodiments to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements of features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes of regions of elements and do not limit example embodiments.

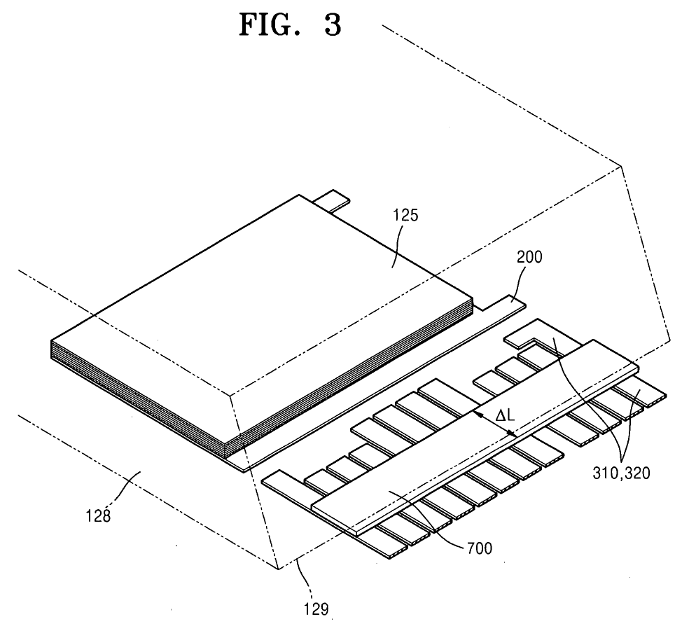

FIG. 2 is a cross-sectional view of first and second semiconductor packages 110 and 120 in which warpage may be reduced or prevented by thermal stress buffers 700, according to example embodiments. FIG. 3 is a perspective view for illustrating positions of the thermal stress buffers 700 illustrated in FIG. 2, according to example embodiments. Configurations and operations of the first and second semiconductor packages 110 and 120 are described with reference to FIGS. 2 and 3.

Referring to FIGS. 2 and 3, the first and second semiconductor packages 110 and 120 may include lead frames 200, semiconductor chips 125 (which may be on the lead frames 200), encapsulants 128 (which may encapsulate the semiconductor chips 125), first and second lead units 310 and 320, portions of which may be exposed outside the first and second semiconductor packages 110 and 120 and through which signals may be transmitted, and the thermal stress buffers 700 which may be deformed by absorbing thermal stress that may be transferred to the first and second lead units 310 and 320 so as to reduce thermal strain transferred to the first and second lead units 310 and 320.

According to example embodiments, the first semiconductor package 110 may be mounted on a module printed circuit board (PCB) 400 and the second semiconductor package 120 may be stacked on the first semiconductor package 110. The first lead unit 310 of the first semiconductor package 110 may be connected to the module PCB 400 by a first solder unit 510, and the second lead unit 320 of the second semiconductor package 120 may be connected to the first lead unit 310 by a second solder unit 520. Virtual lines 600 illustrate warpage profiles of the encapsulants 128 encapsulating the semiconductor chips 125 and virtual lines 610 illustrate a warpage profiles of the first lead unit 310 that is soldered to the second lead unit 320 and a warpage profile of the second lead unit 320 that is soldered to the module PCB 400. The thermal strain of the first and second semiconductor packages 110 and 120 illustrated by the virtual lines 600 may be absorbed by the thermal stress buffers 700 such that the first and second lead units 310 and 320 may have nearly the same thermal strain profiles as the thermal strain profile of the module PCB 400 as illustrated by the virtual lines 610. As such, by reducing the thermal strain of the first and second solder units 510 and 520, the first and second solder units 510 and 520 may be prevented or retarded from being released or cracked and thus second level reliabilities of the first and second semiconductor packages 110 and 120 may be improved.

Configurations and operations of the thermal stress buffers 700 will now be described in detail. In general, an object expands as a temperature increases and contracts as the temperature decreases because atoms or molecules included in the object move actively and vibrate in large amplitudes and thus average distances between the atoms or molecules increase when the temperature increases. In this case, in accordance with a state of a supporting unit or a connection unit of the object (the state is referred to as a constraint condition or a boundary condition), if the expanding or the contracting is constrained, a tensile force or a compressive force corresponding to the constraining may be applied to the object. The tensile force or the compressive force may be calculated into force per unit area, e.g., thermal stress. If heating or cooling is rapidly performed, the thermal stress may be concentrated over a relatively short time such that thermal impact may occur. If the heating or cooling is periodically or repeatedly performed, cracks may occur due to thermal fatigue.

For example, suppose a rod, originally stress free at a temperature To, has two ends in contact with two walls each having an elasticity coefficient k. If the bar is heated to a temperature Tf, the increase in the bar's temperature ΔT (where ΔT=Tf−To) will cause the bar to develop an internal thermal stress a and/or cause the bar to undergo a length variation λ. Where the walls are infinitely stiff (k=∞), the bar cannot expand, the length variation λ is zero, and the thermal stress is σ=EαΔT (where E is the bar's modulus of elasticity and α is the bar's coefficient of thermal expansion). Where the bar is free to expand (k=0), the internal stress of the bar is zero and the length variation λ=αLΔT where L is the length of the bar.

The thermal stress a of a material is determined in accordance with the temperature change ΔT of the material, property values of the material such as the Young's modulus E and the linear expansion coefficient α, and the constraint condition of the material. In order to reduce the thermal stress σ, a material having a low Young's modulus E may be used, a material having a low linear expansion coefficient α may be used, the temperature gap ΔT may be reduced, and the constraint condition may be removed. However, using a material having a low Young's modulus E or a material having a low linear expansion coefficient α in the semiconductor chips 125, the encapsulants 128, the lead frames 200, and the first and second lead units 310 and 320 may be restrictive. It also may be restrictive to reduce the temperature change ΔT of the first and second semiconductor packages 110 and 120. Accordingly, example embodiments are focused on removal of the constraint condition between the encapsulants 128 and the first and second lead units 310 and 320. By freely deforming the thermal stress buffers 700, the first and second lead units 310 and 320 and the first and second solder units 510 and 520 may not be deformed even when the encapsulants 128 are deformed. [0030] Various reliabilities referred to as the second level reliabilities may exist on the first and second semiconductor packages 110 and 120 which may be mounted on the module PCB 400. From among the second level reliabilities, example embodiments may improve reliability of the first and second solder units 510 and 520 when a thermal cycle is applied to the first and second semiconductor packages 110 and 120. Even when warpage of the first and second semiconductor packages 110 and 120 occurs, the first and second solder units 510 and 520 may be prevented or retarded from being released or cracked if the deformation of first and second lead units 310 and 320 are relatively low.

In order to reduce the effect of warpage of the first and second semiconductor packages 110 and 120 on the first and second lead units 310 and 320, the thermal stress buffers 700 may be disposed between portions where the warpage occurs and the first and second lead units 310 and 320. The lower that the Young's modulus of the thermal stress buffers 700 is, the more efficiently the effects of warpage from the first and second semiconductor packages 110 and 120 on the first and second lead units 310 and 320 may be reduced. In other words, heat may be mostly generated from the semiconductor chips 125 and the encapsulants 128 and the first and second lead units 310 and 320 may be less deformed. Thus, the thermal stress buffers 700 may be disposed on portions where the encapsulants 128 contact the first and second lead units 310 and 320. Referring to FIG. 3, the thermal stress buffers 700 may be disposed along outer edges 129 of the encapsulants 128. In order to improve absorption of the thermal stress and flexibility of the thermal strain, portions of the thermal stress buffers 700 may be exposed outside the encapsulants 128. For example, the thermal stress buffers 700 may be disposed so that the outer edges 129 of the encapsulants 128 may be between widths ΔL of the thermal stress buffers 700.

The thermal stress buffers 700 may have adhesion to the encapsulants 128 or the first and second lead units 310 and 320. For example, the thermal stress buffers 700 may be adhesive tape which is disposed between the encapsulants 128 and the first and second lead units 310 and 320 and is adhered to the first and second lead units 310 and 320.

The thermal stress buffers 700 may be formed of a material having a relatively low Young's modulus E and thus the thermal stress buffers 700 may absorb the thermal strain of the encapsulants 128 and may function as stress buffers or strain buffers. Accordingly, the first and second lead units 310 and 320 may not be fully constrained by the thermal strain of the encapsulants 128. The thermal stress buffers 700 may have a lower Young's modulus than the semiconductor chips 125 and the encapsulants 128. For example, the thermal stress buffers 700 may be formed of a polymer material including silicon (Si) or a metallic material having superelastic behavior at an operation temperature of the first and second semiconductor packages 110 and 120.

An example of the metallic material having superelastic behavior is a superelastic shape memory alloy. All materials will mechanically deform when subjected to a stress. When the stress is removed, most materials will recover their original shape provided the applied stress did not exceed the material's yield strength. For conventional materials, exceeding the material's yield strength causes defects in the material which results in plastic deformation. This plastic deformation may impart permanent deformation in the material which will prevent or retard the material from returning to its original shape. Superelastic shape memory alloys respond to high stresses differently from conventional materials. When a superelastic shape memory alloy is subjected to high stresses the high stresses induce a phase transformation which allows the material to strain significantly without incurring material defects. For superelastic materials, a reverse transformation may occur when the stress is removed thus returning the material to its original shape. The superelastic shape memory alloy may be a nickel (Ni)-titanium (Ti) alloy.

The Ni—Ti alloy may have different shape recovery temperatures in accordance with a weight composition ratio of Ni and Ti. For example, if a shape recovery temperature is higher than the operation temperature of the first and second semiconductor packages 110 and 120, a shape memory effect may occur at the operation temperature. If the shape recovery temperature is lower than the operation temperature, a superelastic effect may occur at the operation temperature. In example embodiments, the thermal stress buffers 700 may be formed of a superelastic alloy having a composition ratio in which the superelastic effect occurs at the operation temperature of the first and second semiconductor packages 110 and 120. For example, an atomic composition ratio of Ni and Ti may be between about 50:50 and about 99:1.

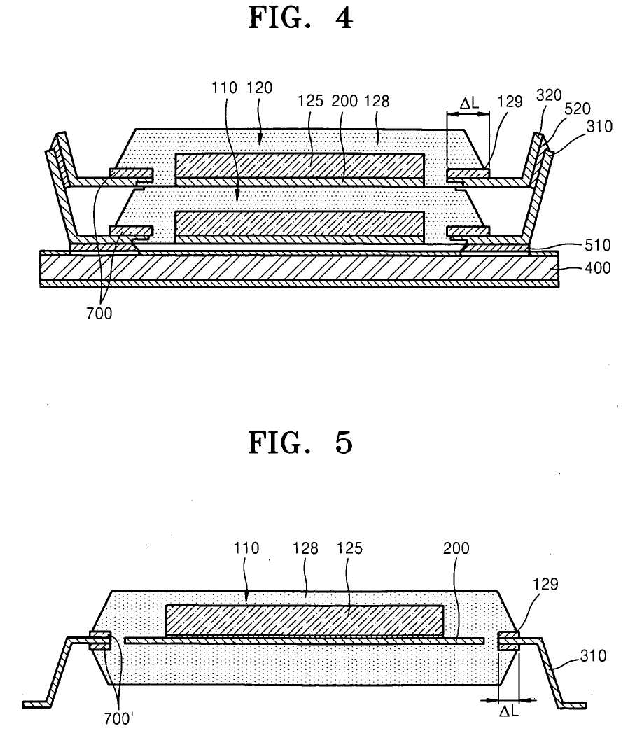

FIGS. 4 and 5 are cross-sectional views of first and second semiconductor packages 110 and 120 before thermal strain occurs, according to example embodiments. In FIG. 4, thermal stress buffers 700 may be adhered to upper surfaces of first and second lead units 310 and 320. In FIG. 5, thermal stress buffers 700′ may be adhered to upper and lower surfaces of the first and second lead units 310 and 320. For example, the thermal stress buffers 700 or 700′ may adhere to at least one of the upper and lower surfaces of the first and second lead units 310 and 320.

Table 1 shows simulation results of strain energy when the thermal stress buffers 700 or 700′ are included and when the thermal stress buffers 700 or 700′ are not included.

TABLE 1

| | strain energy(MPa) | normalized value |
|---|---|---|
| NO thermal stress buffer | 4.06 | 1.00 |
| thermal stress buffer | 2.73 | 0.67 |

As shown in Table 1, when the thermal stress buffers 700 or 700′ are included, the strain energy is reduced to 2.73 MPa, which is only 67% of the strain energy when the thermal stress buffers 700 or 700′ are not included. Due to reduction of the strain energy, when a thermal cycle is applied to first and second semiconductor packages 110 and 120, fatigue life of the first and second semiconductor packages 110 and 120 may be improved.

Regardless of a thermal stress buffer included in a semiconductor package, thermal strains may occur in an encapsulant and a semiconductor chip that is disposed on a lead frame, in accordance with temperature variations. However, according to example embodiments, if the thermal stress buffer is included in the semiconductor package, the thermal stress buffer may deform. Thus, the deformation of a lead unit may be prevented or reduced and the deformation of a solder unit at an end of the lead unit may also be prevented or reduced. Furthermore, the solder unit may be prevented or retarded from being released or cracked and fatigue life that controls second level reliabilities of the semiconductor package may be improved.

While example embodiments have been particularly shown and described with reference to example embodiments thereof, it will be understood by those of ordinary skill in the art that various changes in form and details may be made therein without departing from the spirit and scope of the following claims.

What is claimed is:

1. A semiconductor package comprising:
a semiconductor chip;
an encapsulant encapsulating the semiconductor chip;
a lead unit partially encapsulated by the encapsulant; and
a thermal stress buffer absorbing thermal stress of at least one of the semiconductor chip and the encapsulant.

2. The semiconductor package of claim 1 wherein the thermal stress buffer provides a semiflexible connection between at least one of the semiconductor chip and the encapsulant and the lead unit to reduce the thermal stress generated in at least one of the semiconductor chip and the encapsulant and transfers the thermal stress generated in the at least one of the semiconductor chip and the encapsulant to the lead unit.

3. The semiconductor package of claim 1, wherein the thermal stress buffer has a lower Young's modulus than the semiconductor chip and the encapsulant.

4. The semiconductor package of claim 3, wherein the thermal stress buffer is a polymer material including silicon (Si).

5. The semiconductor package of claim 3, wherein the thermal stress buffer is a metallic material having superelastic behavior at an operation temperature of the semiconductor package.

6. The semiconductor package of claim 1, wherein the thermal stress buffer adheres to the encapsulant.

7. The semiconductor package of claim 1, wherein the thermal stress buffer adheres to the lead unit.

8. The semiconductor package of claim 1, wherein the thermal stress buffer is along an outer edge of the encapsulant.

9. The semiconductor package of claim 8, wherein a portion of the thermal stress buffer is exposed outside the encapsulant.

10. The semiconductor package of claim 1, wherein the thermal stress buffer is an adhesive tape between the encapsulant and the lead unit and adheres to the lead unit.

11. The semiconductor package of claim 1, wherein the thermal stress buffer is on both upper and lower surfaces of the lead unit.

12. The semiconductor package of claim 1, wherein the thermal stress buffer adheres to at least one of upper and lower surfaces of the lead unit.

13. The semiconductor package of claim 1, wherein the thermal stress buffer reduces thermal strain of a solder unit that mounts the lead unit on a module printed circuit board when warpage of the semiconductor package occurs in accordance with temperature variations, and has a lower Young's modulus than the semiconductor chip, the encapsulant, and the lead unit.
